(19) United States
(12) Patent Application Publication
(10) Pub. No.: US 2018/0226476 A1
(43) Pub. Date: Aug. 9, 2018

(54) ARRAY SUBSTRATE AND MANUFACTURING METHOD THEREOF, DISPLAY PANEL AND DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: Zhichao ZHANG, Beijing (CN); Tsung Chieh KUO, Beijing (CN); Zheng LIU, Beijing (CN); Xiaoxiang ZHANG, Beijing (CN); Xi CHEN, Beijing (CN); Mingxuan LIU, Beijing (CN)

(21) Appl. No.: 15/325,597

(22) PCT Filed: Oct. 30, 2015
(86) PCT No.: PCT/CN2015/093387

§ 371 Date: Jan. 11, 2017

(30) Foreign Application Priority Data
Jun. 26, 2015 (CN) 201510369478.6

(51) Int. Cl. H01L 29/417; H01L 29/786; H01L 27/12

(52) U.S. Cl. CPC H01L 29/41733; H01L 29/78606; H01L 27/124; H01L 27/1203; H01L 29/78696

(57) ABSTRACT

An array panel and a manufacturing method thereof, a display panel and a display device are provided. The manufacturing method includes: forming first conducting patterns, second conducting patterns and metal connection lines on a base substrate, the metal connection lines being connected to the first conducting patterns and the second conducting patterns; and etching the metal connection lines so as to isolate the first conducting patterns from the second conducting patterns.

### TECHNICAL FIELD

Embodiments of the present invention relate to an array substrate and a manufacturing method thereof, a display panel and a display device.

### BACKGROUND

In a field of Thin Film Transistor-Liquid Crystal Display (TFT-LCD), a High Advanced Super Dimension Switch (HADS) has characteristics of high aperture ratio and the like and is widely applied in a manufacturing process of a small-sized product. However, a display panel in an HADS mode has an Electro-Static discharge (ESD) problem. Occurrence of ESD is related to an electric potential difference existing between metal wires. In a manufacturing process of an array substrate, because of equipment static electricity, friction static electricity or process discharge or the like, metal blocks or metal wires having been manufactured on the substrate can gather charges. Because of circuit arrangement, the charges accumulated between the metal blocks or the metal wires are different in polarity and cannot be counteracted, and finally, the electric potential difference is generated between the metal blocks and the metal wires. When the electric potential difference reaches a certain numerical value, ESD can happen between the metal blocks and the metal wires.

### SUMMARY

Embodiments of the present invention provide an array substrate and a manufacturing method thereof, a display panel and a display device, used for eliminating a problem that ESD happens between metal blocks and metal wires in a period of a manufacturing process of the array substrate.

In one aspect, an embodiment of the present invention provides a manufacturing method of an array substrate, comprising: forming a first conductive pattern, a second conductive pattern and a metal connection line on a base substrate, the metal connection line being connected with the first conductive pattern and the second conductive pattern; and etching the metal connection line to make the first conductive pattern and the second conductive pattern insulated from each other.

In another aspect, an embodiment of the present invention further provides an array substrate, which is prepared according to any one of the above methods.

In still another aspect, an embodiment of the present invention further provides a display panel, comprising the array substrate.

In yet another aspect, an embodiment of the present invention further provides a display device, comprising the display panel.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a flow diagram of a manufacturing method of an array substrate provided by Embodiment I of the present invention;

FIGS. 2a to 2f are plan views of the array substrate formed in Embodiment I;

FIGS. 3a to 3f are sectional views corresponding to the plan views illustrated by FIGS. 2a to 2f;

FIGS. 4a to 4f are plan views of an array substrate formed in Embodiment II;

FIGS. 5a to 5f are sectional views corresponding to the plan views illustrated by FIGS. 4a to 4f;

FIGS. 6a to 6f are plan views of an array substrate formed in Embodiment IV; and

FIGS. 7a to 7f are sectional views corresponding to the plan views illustrated by FIGS. 6a to 6f.

### DETAILED DESCRIPTION

In order to clearly illustrate purposes, technical solutions and advantages of the embodiments of the disclosure, the technical solutions of the embodiments of the present invention will be described in a clearly and fully understandable way in connection with the drawings in the embodiments of the present invention. It is obvious that the described embodiments are just a part but not all of the embodiments of the present invention. Based on the described embodiments herein, those skilled in the art can obtain other embodiment(s), without any inventive work, which should be within the scope of the present invention.

In order to make those skilled in the art better understand the technical solutions of the embodiments of the present invention, an array substrate and a manufacturing method thereof, a display panel and a display device provided by the embodiments of the present invention will be described in detail in connection with the drawings. The embodiments of the present invention only describe an array substrate in an HADS mode, but array substrates in other display modes, such as, a TN mode, a VA mode or an IPS mode are also within the scope of the present invention. In addition, the present invention only describes an HADS 5 Mask process, but an HADS 4 Mask process or other preparation processes related to the present invention are also within the scope of the present invention.

### Embodiment I

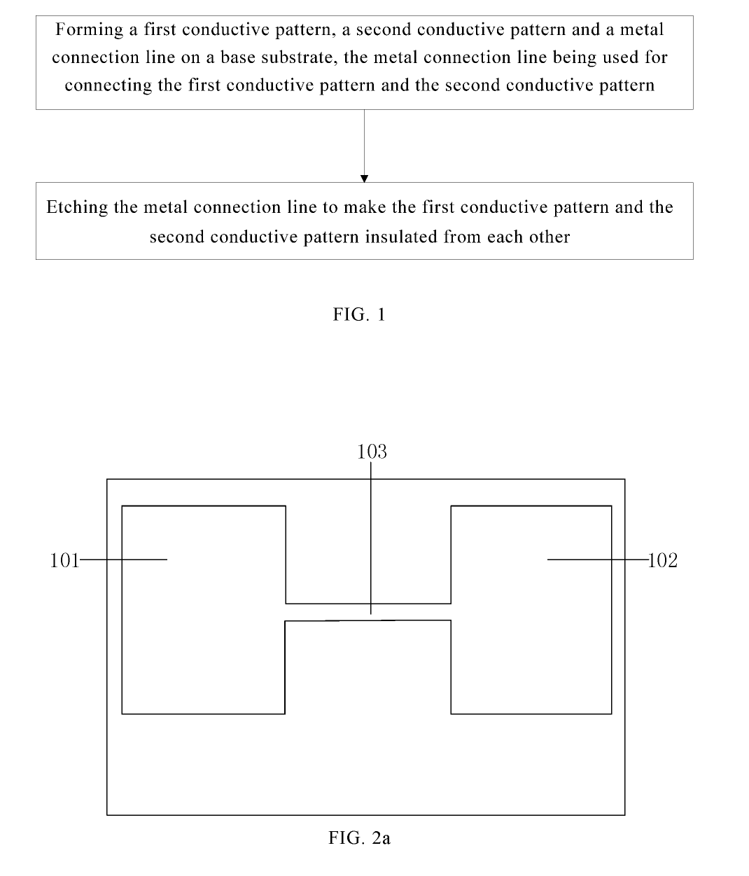

FIG. 1 is a flow diagram of a manufacturing method of an array substrate provided by Embodiment I of the present invention. As illustrated in FIG. 1, the manufacturing method of the array substrate includes:

Step 1001: forming a first conductive pattern, a second conductive pattern and a metal connection line on a base substrate 100, the metal connection line being connected with the first conductive pattern and the second conductive pattern.

In the embodiment, the first conductive pattern includes a first gate electrode metal pattern, the second conductive pattern includes a second gate electrode metal pattern, and the gate electrode metal pattern includes a gate electrode and a gate line.

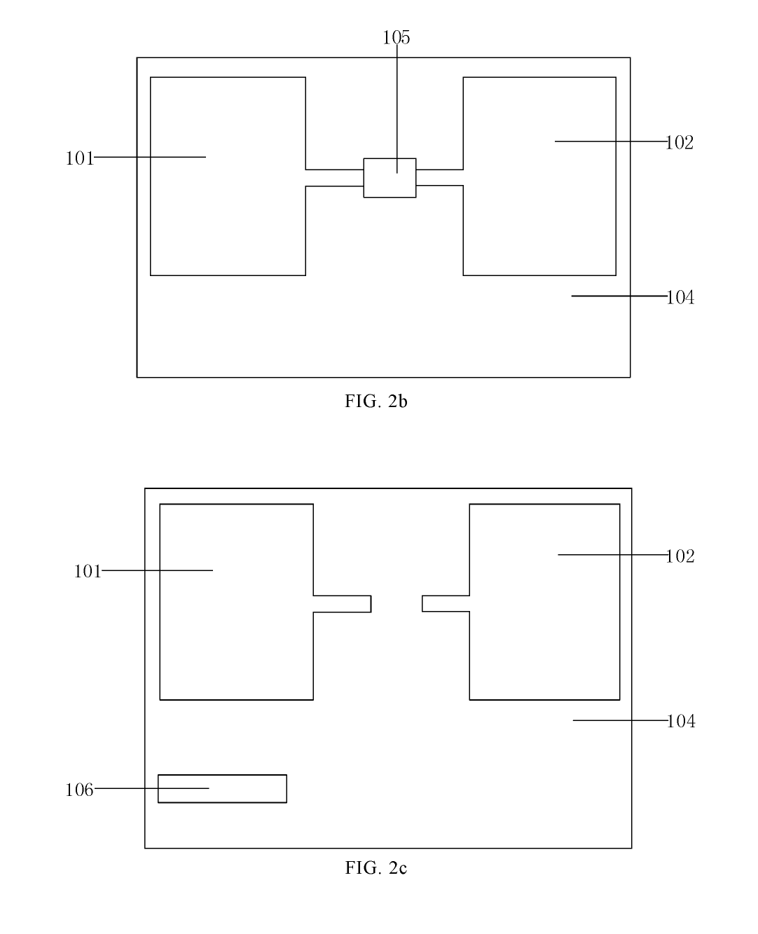

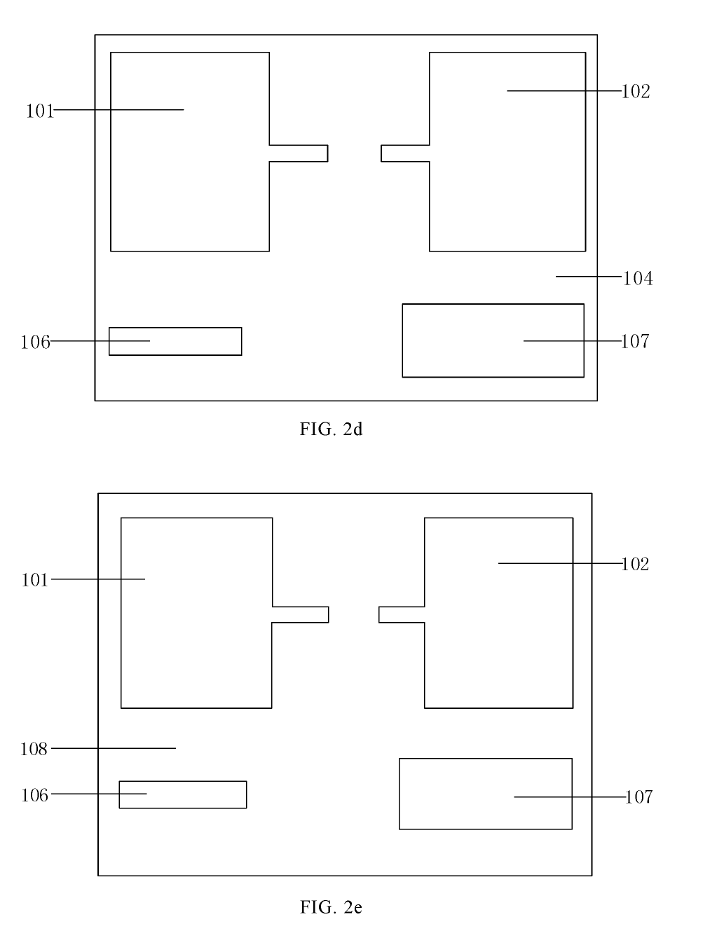

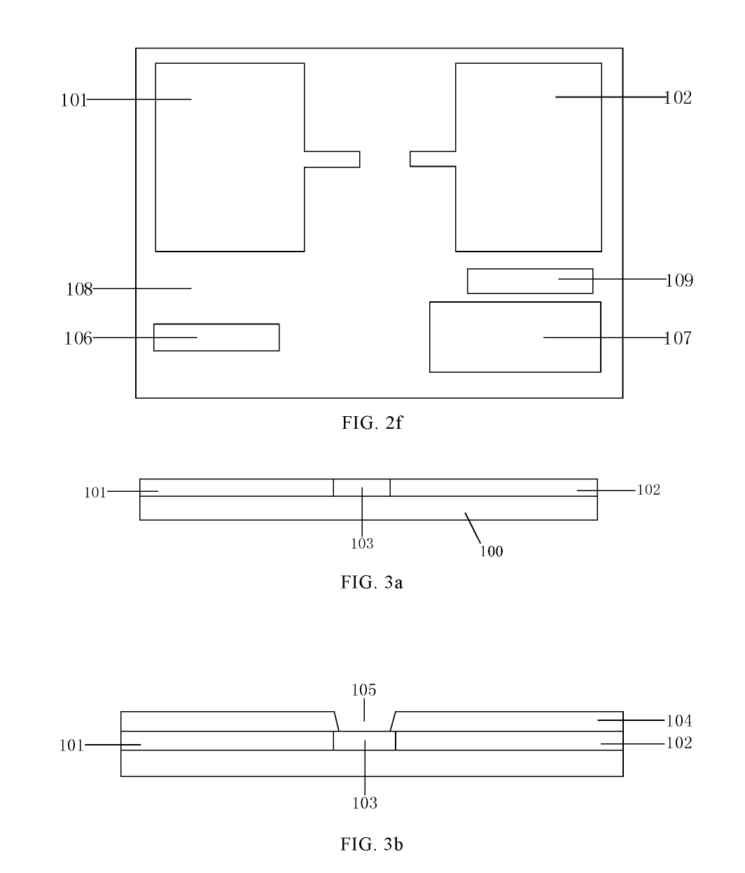

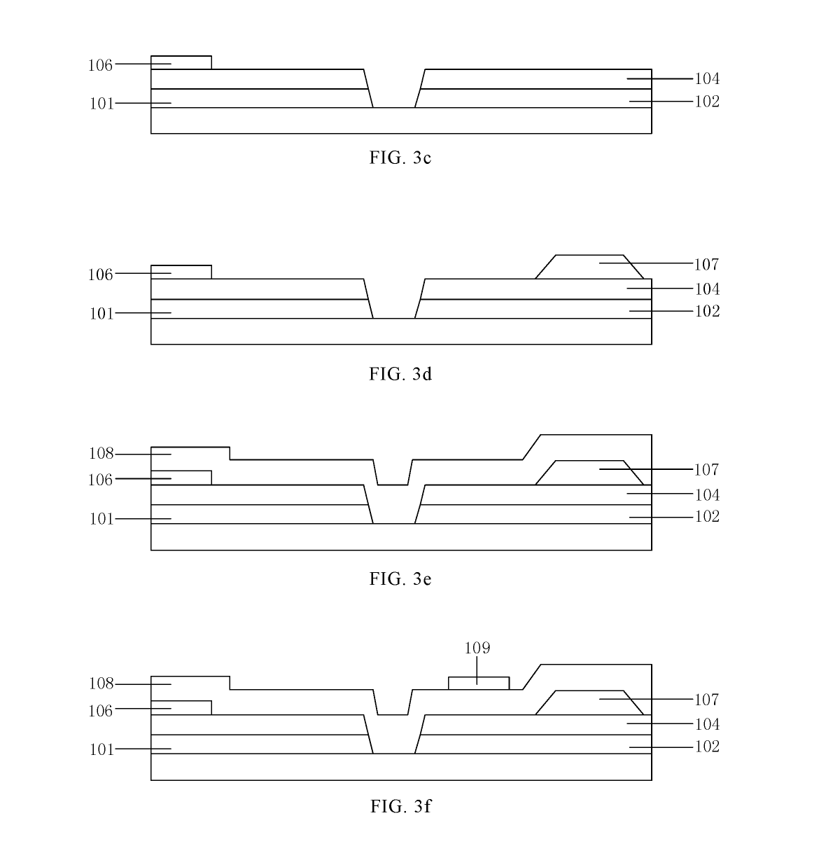

FIGS. 2a to 2f are plan views of the array substrate formed by Embodiment I, and FIGS. 3a to 3f are sectional views corresponding to the plan views illustrated by FIGS. 2a to 2f. As illustrated in FIGS. 2a to 2f and FIGS. 3a to 3f, the first gate electrode metal pattern 101, the second gate electrode metal pattern 102 and the metal connection line 103 are formed on the base substrate 100, and the metal connection line 103 is connected with the first gate electrode metal pattern 101 and the second gate electrode metal pattern 102. The metal connection line 103 provided by the embodiment is connected with the first gate electrode metal pattern 101 and the second gate electrode metal pattern 102 to make a voltage of the first gate electrode metal pattern 101 and a voltage of the second gate electrode metal pattern 102 in a technological process kept to be the same, and therefore an electric potential difference between the first gate electrode metal pattern 101 and the second gate electrode metal pattern 102 can be balanced, an electrostatic discharge phenomenon is avoided, finally, endurance capacity of a product on the electrostatic discharge phenomenon is improved, and a product yield is increased.

In the embodiment, a gate insulating layer and an active layer 104 are formed above the first gate electrode metal pattern 101, the second gate electrode metal pattern 102 and the metal connection line 103. What needs to be explained is that, because the gate insulating layer and the active layer 104 are formed by a single patterning process, in order to facilitate description, the gate insulating layer is not indicated in FIGS. 2a to 2f and FIGS. 3a to 3f. A first via hole 105 corresponding to the meal connection line 103 is opened in the gate insulating layer and the active layer 104, and the metal connection line 103 is exposed through the first via hole 105.

Step 1002: etching the metal connection line to make the first conductive pattern and the second conductive pattern insulated from each other.

In the embodiment, a transparent electrode thin film is formed above the active layer 104, the transparent electrode thin film and the metal connection line 103 are etched to form a first transparent electrode 106. Exemplarily, an etching process comprises wet etching. In the embodiment, the metal connection line 103 is removed through the etching process to make the first gate electrode metal pattern 101 and the second gate electrode metal pattern 102 disconnected, therefore avoiding influence on work performance of the first gate electrode metal pattern 101 and work performance of the second gate electrode metal pattern 102.

In the embodiment, a source electrode metal pattern and a drain electrode metal pattern are formed above the active layer 104, the source electrode metal pattern includes a source electrode and a data line, and the drain electrode metal pattern includes a drain electrode. In the embodiment, the source electrode metal pattern and the drain electrode metal pattern are jointly called a source and drain electrode metal pattern. A passivation layer 108 is formed above a source and drain electrode metal pattern 107 and the first transparent electrode 106, a second transparent electrode 109 is formed above the passivation layer 108. In the first transparent electrode 106 and the second transparent electrode 109, what is connected with the drain electrode is a pixel electrode, and the other is a common electrode.

The manufacturing method of the array substrate provided by the embodiment comprises: forming the first conductive pattern, the second conductive pattern and the metal connection line on the base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make voltage of the first conductive con pattern and voltage of the second conductive pattern in the technological process kept to be the same, and therefore an electric potential difference between the first conductive pattern and the second conductive pattern can be balanced, the electrostatic discharge phenomenon is avoided, finally, the endurance capacity of the product on the electrostatic discharge phenomenon is improved, and the product yield is increased. In addition, in the embodiment, the metal connection line is removed through the etching process to make the first conductive pattern and the second conductive pattern insulated from each other, therefore avoiding influence on work performance of the first conductive pattern and work performance of the second conductive pattern.

### Embodiment II

The embodiment provides a manufacturing method of an array substrate. Referring to FIG. 1, the manufacturing method comprises:

Step 1001: forming a first conductive pattern, a second conductive pattern and a metal connection line on a base substrate, the metal connection line being connected with the first conductive pattern and the second conductive pattern.

In the embodiment, the first conductive pattern includes a first gate electrode metal pattern, the second conductive pattern includes a second gate electrode metal pattern, and the gate electrode metal pattern includes a gate electrode and a gate line.

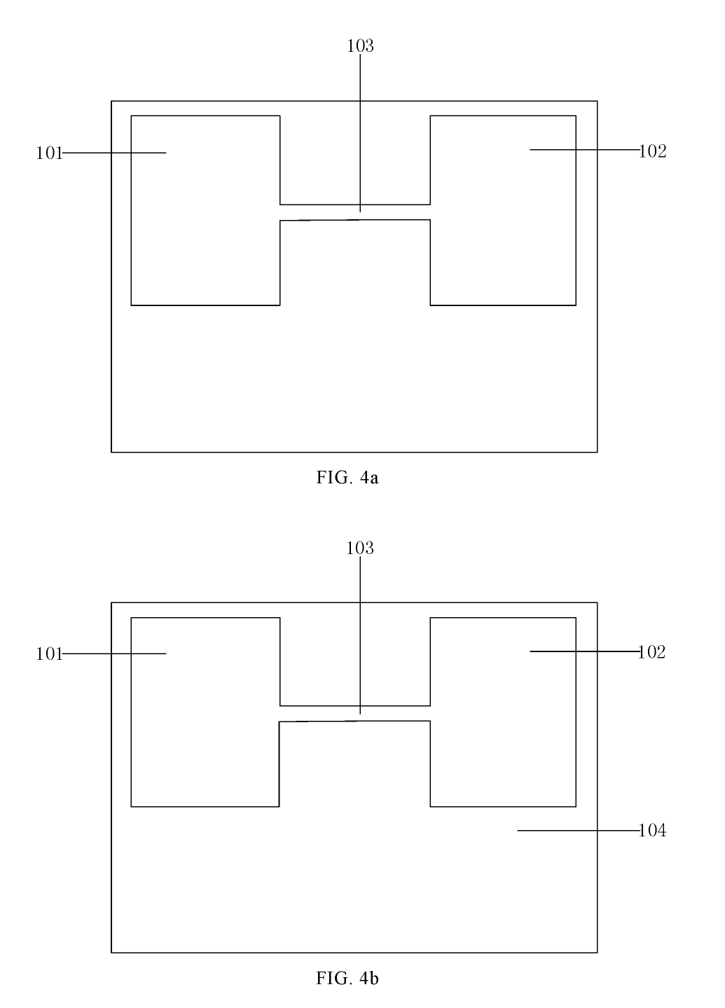

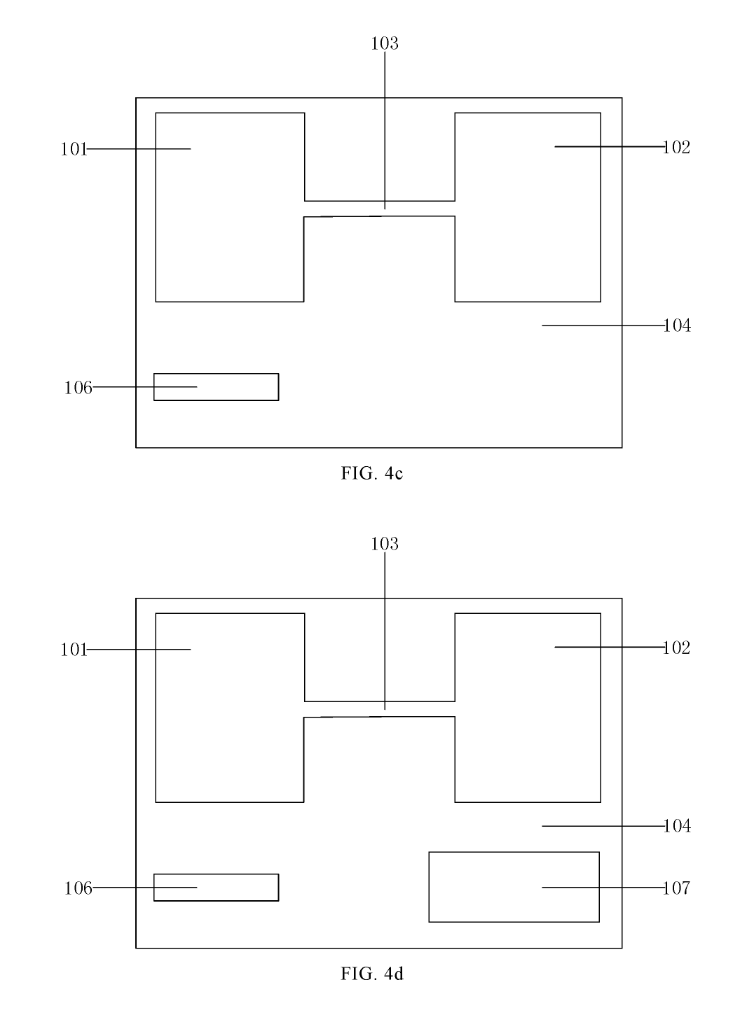

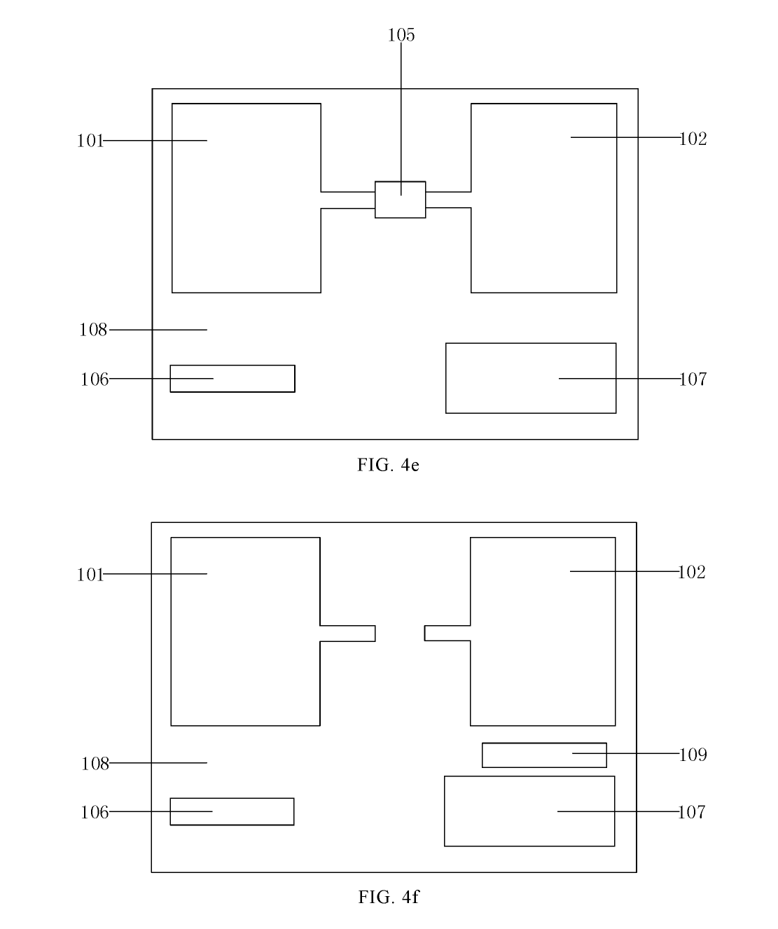

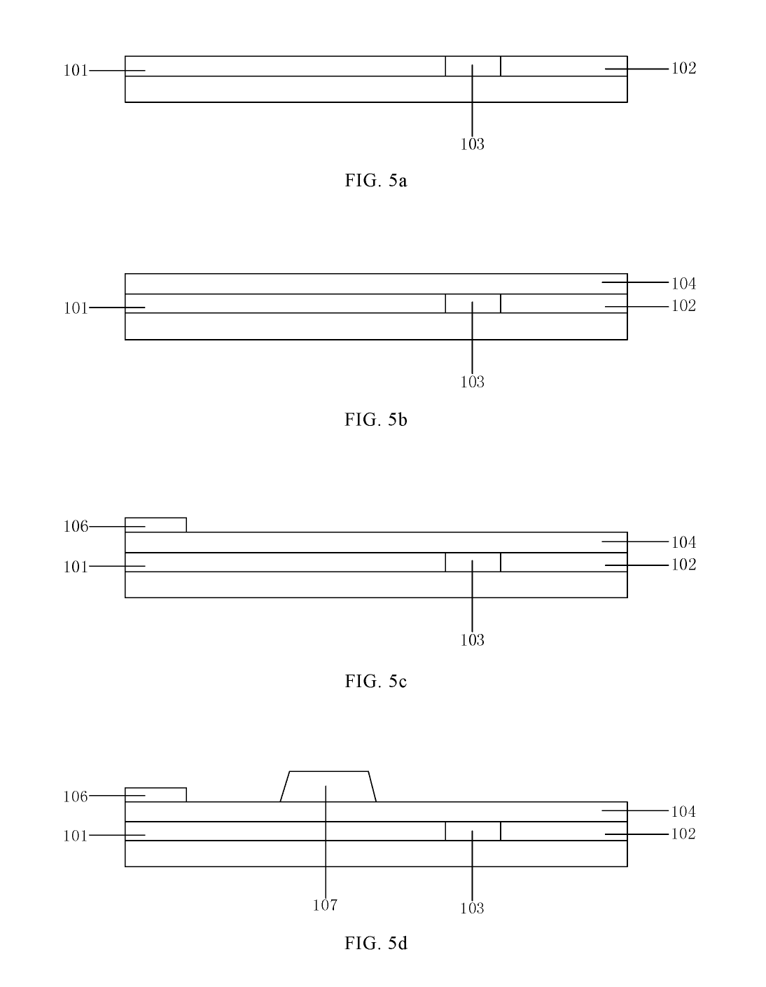

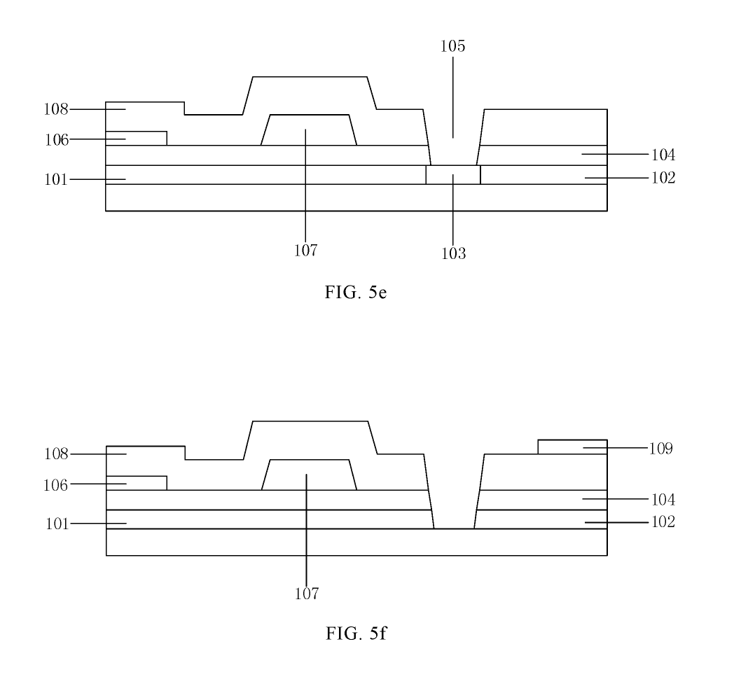

FIGS. 4a to 4f are plan views of the array substrate formed in Embodiment II, and FIGS. 5a to 5f are sectional views corresponding to the plan views illustrated by FIGS. 4a to 4f. As illustrated in FIGS. 4a to 4f and FIGS. 5a to 5f, the first gate electrode metal pattern 101, the second gate electrode metal pattern 102 and the metal connection line 103 are formed on the base substrate, and the metal connection line 103 is connected with the first gate electrode metal pattern 101 and the second gate electrode metal pattern 102. The metal connection line 103 provided by the embodiment is connected with the first gate electrode metal pattern 101 and the second gate electrode metal pattern 102 to make a voltage of the first gate electrode metal pattern 101 and a voltage of the second gate electrode metal pattern 102 in a technological process kept to be the same, and therefore an electric potential difference between the first gate electrode metal pattern 101 and the second gate electrode metal pattern 102 can be balanced, an electrostatic discharge phenomenon is avoided, finally, endurance capacity of a product on the electrostatic discharge phenomenon is improved, and a product yield is increased.

In the embodiment, a gate insulating layer and an active layer 104 are formed above the first gate electrode metal pattern 101, the second gate electrode metal pattern 102 and the metal connection line 103. What needs to be explained is that, because the gate insulating layer and the active layer 104 are formed by a single patterning process, in order to facilitate description, the gate insulating layer is not indicated in FIGS. 4a to 4f and FIGS. 5a to 5f.

Step 1002: etching the metal connection line to make the first conductive pattern and the second conductive pattern insulated from each other.

In the embodiment, a transparent electrode 106 is formed above the active layer 104. A source electrode metal pattern and a drain electrode metal pattern are formed above the active layer 104, the source electrode metal pattern includes a source electrode and a data line, and the drain electrode metal pattern includes a drain electrode. In the embodiment, the source electrode metal pattern and the drain electrode metal pattern are jointly called a source and drain electrode metal pattern. A passivation layer 108 is formed above the source and drain electrode metal pattern 107 and the first transparent electrode 106, a first via hole 105 corresponding to the meal connection line 103 is opened in the passivation layer 108, and the metal connection line 103 is exposed through the first via hole 105.

Exemplarily, a via hole corresponding to the first via hole is further formed in the active layer 4, and therefore the metal connection line 103 can be exposed.

In the embodiment, a transparent electrode thin film is formed above the passivation layer 108, the transparent electrode thin film and the metal connection line 103 are etched to form a second transparent electrode 109. Exemplarily, an etching process comprises wet etching. In the embodiment, the metal connection line 103 is removed through the etching process to make the first gate electrode metal pattern 101 and the second gate electrode metal pattern 102 disconnected, therefore avoiding influence on work performance of the first gate electrode metal pattern 101 and work performance of the second gate electrode metal pattern 102. In addition, in the first transparent electrode 106 and the second transparent electrode 109, what is connected with the drain electrode is a pixel electrode, and the other is a common electrode.

The manufacturing method of the array substrate provided by the embodiment comprises: forming the first conductive pattern, the second conductive pattern and the metal connection line on the base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in the technological process kept to be the same, and therefore an electric potential difference between the first conductive pattern and the second conductive pattern can be balanced, the electrostatic discharge phenomenon is avoided, finally, the endurance capacity of the product on the electrostatic discharge phenomenon is improved, and the product yield is increased. In addition, in the embodiment, the metal connection line is removed through the etching process to make the first conductive pattern and the second conductive pattern insulated from each other, therefore avoiding influence on work performance of the first conductive pattern and work performance of the second conductive pattern.

### Embodiment III

The embodiment provides a manufacturing method of an array substrate. Referring to FIG. 1, the manufacturing method comprises:

Step 1001: forming a first conductive pattern, a second conductive pattern and a metal connection line on a base substrate, the metal connection line being connected with the first conductive pattern and the second conductive pattern.

In the embodiment, the first conductive pattern includes a source electrode metal pattern, the second conductive pattern includes a drain electrode metal pattern, the source electrode metal pattern includes a source electrode and a data line, and the drain electrode metal pattern includes a drain electrode.

In the embodiment, a gate electrode metal pattern is formed on the base substrate and includes a gate electrode and a gate line. A gate insulating layer and an active layer are formed above the gate electrode metal pattern, and a first transparent electrode is formed above the active layer. The source electrode metal pattern, the drain electrode metal pattern and the metal connection line are formed above the active layer, and the metal connection line is connected with the source electrode metal pattern and the drain electrode metal pattern. The metal connection line provided by the embodiment is connected with the source electrode metal pattern and the drain electrode metal pattern to make a voltage of the source electrode metal pattern and a voltage of the drain electrode metal pattern in a technological process kept to be the same, and therefore an electric potential difference between the source electrode metal pattern and the drain electrode metal pattern can be balanced, an electrostatic discharge phenomenon is avoided, finally, endurance capacity of a product on the electrostatic discharge phenomenon is improved, and a product yield is increased.

Step 1002: etching the metal connection line to make the first conductive pattern and the second conductive pattern insulated from each other.

A passivation layer is formed above the source electrode metal pattern, the drain electrode metal pattern and the first transparent electrode, a first via hole corresponding to the metal connection line is formed in the passivation layer, and the metal connection line is exposed through the first via hole.

In the embodiment, a transparent electrode thin film is formed above the passivation layer, and the transparent electrode thin film and the metal connection line are etched to form a second transparent electrode. In the embodiment, the metal connection line is removed through an etching process to make the source electrode metal pattern and the drain electrode metal pattern disconnected, therefore avoiding influence on work performance of the source electrode metal pattern and work performance of the drain electrode metal pattern. In addition, in the first transparent electrode and the second transparent electrode, what is connected with the drain electrode is a pixel electrode, and the other is a common electrode.

The manufacturing method of the array substrate provided by the embodiment comprises: forming the first conductive pattern, the second conductive pattern and the metal connection line on the base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in the technological process kept to be the same, and therefore an electric potential difference between the first conductive pattern and the second conductive pattern can be balanced, the electrostatic discharge phenomenon is avoided, finally, the endurance capacity of the product on the electrostatic discharge phenomenon is improved, and the product yield is increased. In addition, in the embodiment, the metal connection line is removed through the etching process to make the first conductive pattern and the second conductive pattern insulated from each other, therefore avoiding influence on work performance of the first conductive pattern and work performance of the second conductive pattern.

### Embodiment IV

The embodiment provides a manufacturing method of an array substrate. Referring to FIG. 1, the manufacturing method comprises:

Step 1001: forming a first conductive pattern, a second conductive pattern and a metal connection line on a base substrate, the metal connection line being connected with the first conductive pattern and the second conductive pattern.

In the embodiment, the metal connection line includes a first sub-connection line and a second sub-connection line which are connected with each other, the first sub-connection line is connected with the first conductive pattern, the second sub-connection line is connected with the second conductive pattern, the first conductive pattern includes a gate electrode metal pattern, and the second conductive pattern includes a source electrode metal pattern or a drain electrode metal pattern. The second conductive pattern provided by the embodiment is the source electrode metal pattern, and regarding the content that the second conductive pattern is the drain electrode metal pattern, please refer to Embodiment V. The gate electrode metal pattern includes a gate electrode and a gate line, the source electrode metal pattern includes a source electrode and a data line, and the drain electrode metal pattern includes a drain electrode.

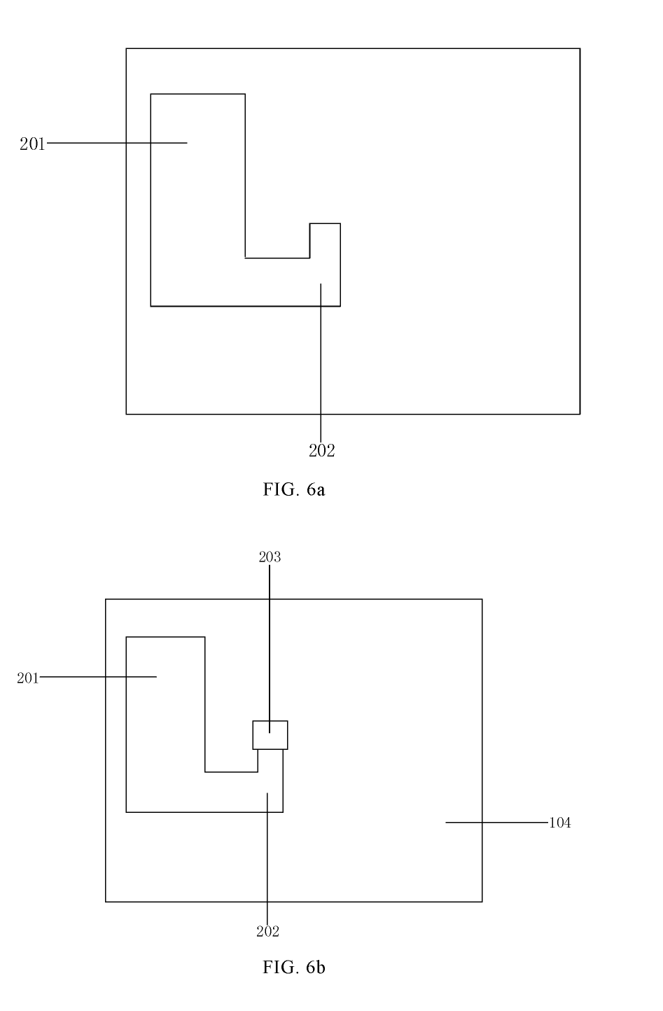

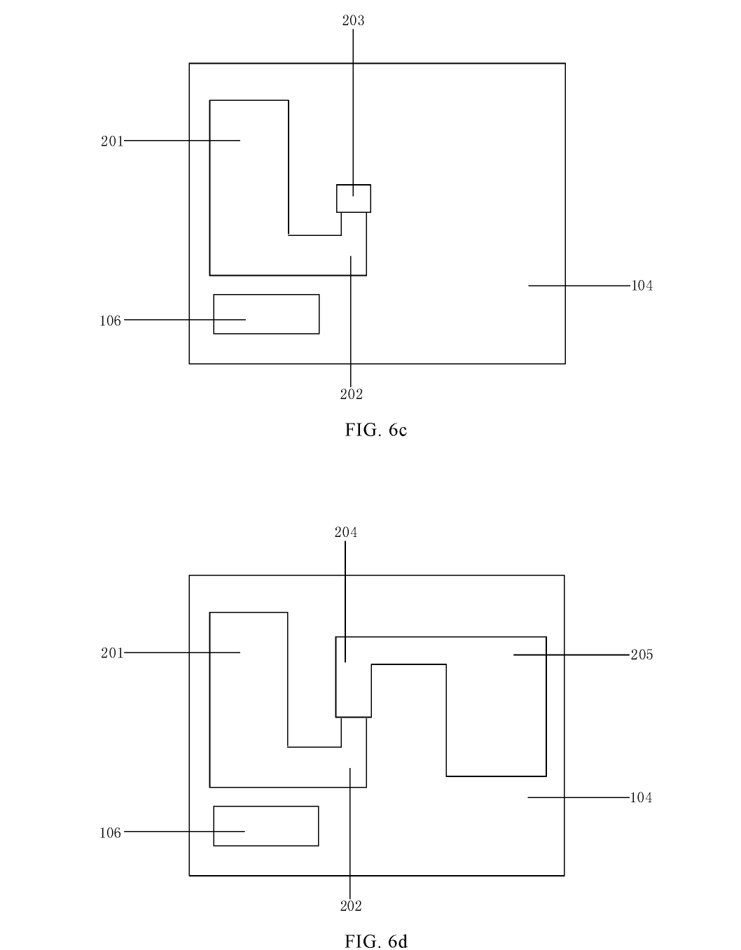

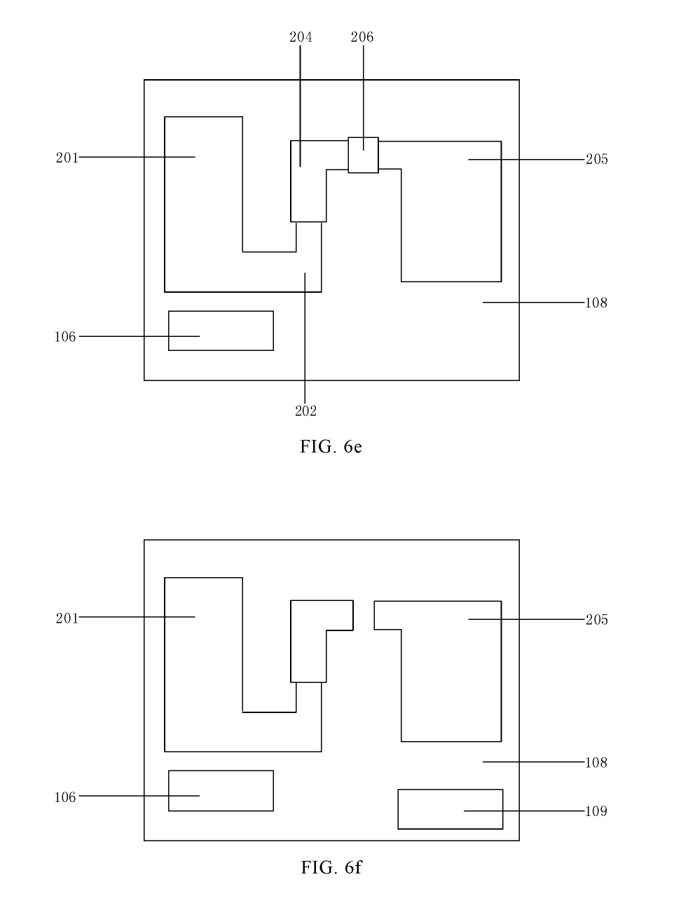

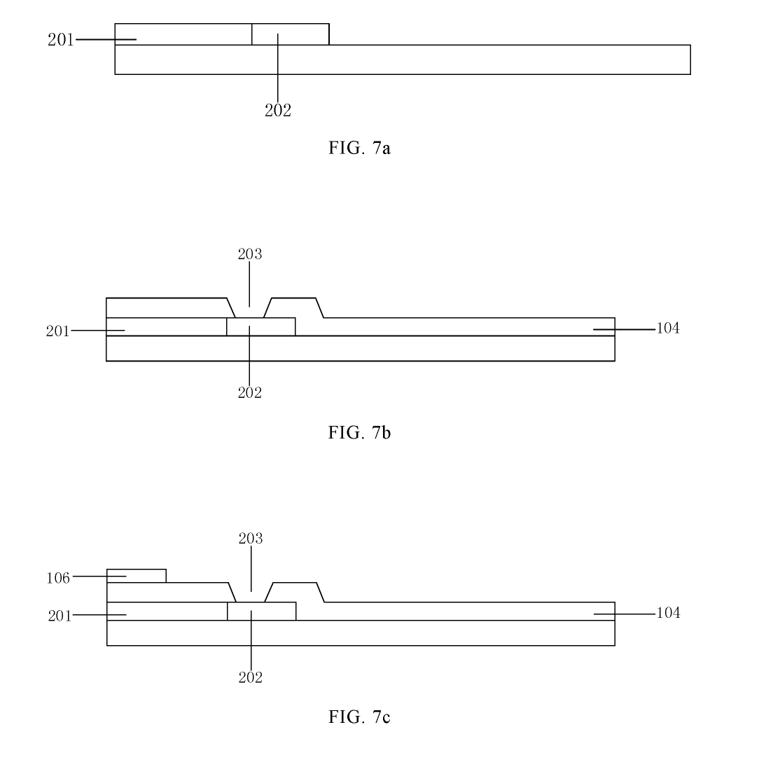

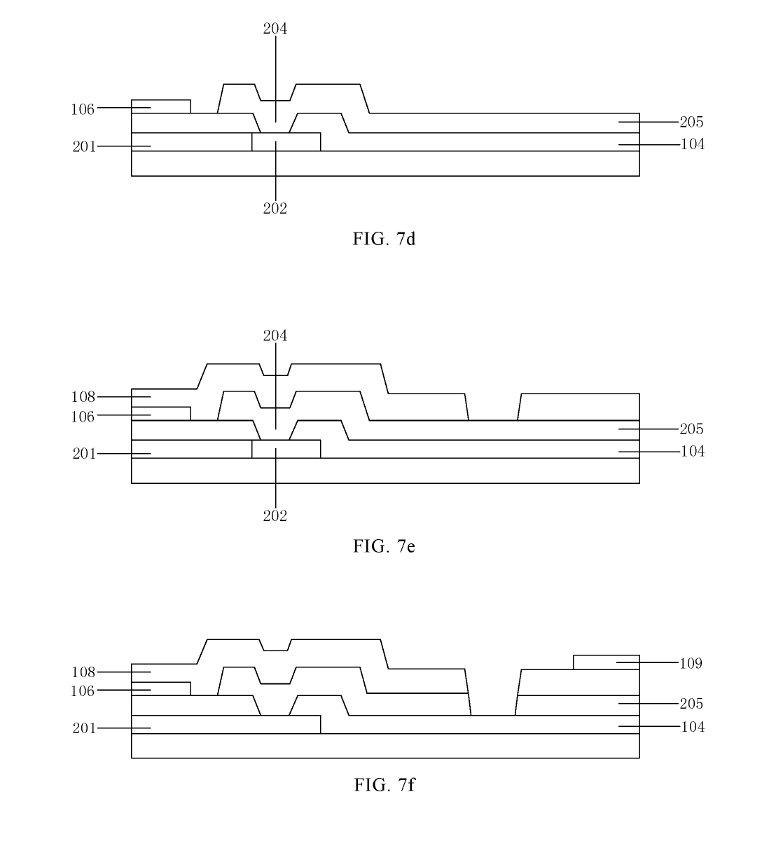

FIGS. 6a to 6f are plan views of the array substrate formed in Embodiment IV and FIGS. 7a to 7f are sectional views corresponding to the plan views illustrated by FIGS. 6a to 6f. As illustrated in FIGS. 6a to 6f and FIGS. 7a to 7f, the gate electrode metal pattern 201 and the first sub-connection line 202 are formed on the base substrate, and the first sub-connection line 202 is connected with the gate electrode metal pattern 201. A gate insulating layer and an active layer are formed above the gate electrode metal pattern 201 and the first sub-connection line 202. What needs to be explained is that, because the gate insulating layer and the active layer are formed by a single patterning process, in order to facilitate description, the gate insulating layer is not indicated in FIGS. 6a to 6f and FIGS. 7a to 7f. A second via hole 203 corresponding to the first sub-connection line 202 is opened in the gate insulating layer and the active layer, and the first sub-connection line 202 is exposed through the second via hole 203.

In the embodiment, a first transparent electrode 106 is formed above the active layer 104, the source electrode metal pattern, the drain electrode metal pattern and the second sub-connection wire 204 are formed above the active layer 104. What needs to be explained is that, because the source electrode metal pattern and the drain electrode metal pattern are formed by a single patterning process, in order to facilitate description, the drain electrode metal pattern is not indicated in FIGS. 6a to 6f and FIGS. 7a to 7f. The second sub-connection wire 204 is connected with the source electrode metal pattern 205 and connected with the first sub-connection line 202 through the second via hole 203, the source electrode metal pattern includes the source electrode and the data line, and the drain electrode metal pattern includes the drain electrode. The first sub-connection line 202 and the second sub-connection wire 204 provided by the embodiment are connected with the gate electrode metal pattern 201 and the source electrode metal pattern 205 to make a voltage of the gate electrode metal pattern 201 and a voltage of the source electrode metal pattern 205 in a technological process kept to be the same, and therefore an electric potential difference between the gate electrode metal pattern 201 and the source electrode metal pattern 205 can be balanced, an electrostatic discharge phenomenon is avoided, finally, the endurance capacity of the product on the electrostatic discharge phenomenon is improved, and the product yield is increased.

Step 1002: etching the metal connection line to make the first conductive pattern and the second conductive pattern insulated from each other.

In the embodiment, a passivation layer 108 is formed above the source electrode metal pattern 205 and the first transparent electrode 106, a first via hole 105 corresponding to the second sub-connection line 204 is formed in the passivation layer 108, and the second sub-connection line 204 is exposed through the first via hole 105. Of course, a first via hole 105 corresponding to the first sub-connection line 202 can also be formed in the passivation layer 108.

In the embodiment, a transparent electrode thin film is formed above the passivation layer 108, the transparent electrode thin film and the second sub-connection line 204 are etched to form a second transparent electrode 109. In the embodiment, part or all of the second sub-connection line 204 is removed by an etching process, so that the gate electrode metal pattern 201 and the source electrode metal pattern 205 can be disconnected, therefore avoiding influence on work performance of the gate electrode metal pattern 201 and work performance of the source electrode metal pattern 205. In addition, in the first transparent electrode 106 and the second transparent electrode 109, what is connected with the drain electrode is a pixel electrode, and the other is a common electrode.

The manufacturing method of the array substrate provided by the embodiment comprises: forming the first conductive pattern, the second conductive pattern and the metal connection line on the base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in the technological process kept to be the same, and therefore an electric potential difference between the first conductive pattern and the second conductive pattern can be balanced, the electrostatic discharge phenomenon is avoided, finally, the endurance capacity of the product on the electrostatic discharge phenomenon is improved, and the product yield is increased. In addition, in the embodiment, the metal connection line is removed through the etching process to make the first conductive pattern and the second conductive pattern insulated from each other, therefore avoiding influence on work performance of the first conductive pattern and work performance of the second conductive pattern.

### Embodiment V

The embodiment provides a manufacturing method of an array substrate. Referring to FIG. 1, the manufacturing method comprises:

Step 1001: forming a first conductive pattern, a second conductive pattern and a metal connection line on a base substrate, the metal connection line being connected with the first conductive pattern and the second conductive pattern.

In the embodiment, the metal connection line includes a first sub-connection line and a second sub-connection line which are connected with each other, the first sub-connection line is connected with the first conductive pattern, the second sub-connection line is connected with the second conductive pattern, the first conductive pattern includes a gate electrode metal pattern, the second conductive pattern includes a drain electrode metal pattern, the gate electrode metal pattern includes a gate electrode and a gate line, a source electrode metal pattern includes a source electrode and a data line, and the drain electrode metal pattern includes a drain electrode.

Step 1002: etching the metal connection line to make the first conductive pattern and the second conductive pattern insulated from each other.

A difference between the manufacturing method provided by the embodiment and the manufacturing method provided by the above Embodiment IV lies in that the second sub-connection line in the embodiment is connected with the drain electrode metal pattern, while the second sub-connection line in the above Embodiment IV is connected with the source electrode metal pattern; and the rest are completely same. Thus, detailed content can refer to description of the above Embodiment IV and will not be repeated herein.

The manufacturing method of the array substrate provided by the embodiment comprises: forming the first conductive pattern, the second conductive pattern and the metal connection line on the base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in a technological process kept to be the same, and therefore an electric potential difference between the first conductive pattern and the second conductive pattern can be balanced, an electrostatic discharge phenomenon is avoided, finally, endurance capacity of a product on the electrostatic discharge phenomenon is improved, and a product yield is increased. In addition, in the embodiment, the metal connection line is removed through an etching process to make the first conductive pattern and the second conductive pattern insulated from each other, therefore avoiding influence on work performance of the first conductive pattern and work performance of the second conductive pattern.

### Embodiment VI

The embodiment provides an array substrate, which is prepared according to any one of the methods in Embodiment I to Embodiment V, detailed content of a manufacturing method of the array substrate can refer to description of Embodiment I to Embodiment V and will not be repeated herein.

In the array substrate provided by the embodiment, the manufacturing method of the array substrate comprises: forming the first conductive pattern, the second conductive pattern and the metal connection line on the base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in a technological process kept to be the same, and therefore an electric potential difference between the first conductive pattern and the second conductive pattern can be balanced, an electrostatic discharge phenomenon is avoided, finally, endurance capacity of a product on the electrostatic discharge phenomenon is improved, and a product yield is increased. In addition, in the embodiment, the metal connection line is removed through an etching process to make the first conductive pattern and the second conductive pattern insulated from each other, therefore avoiding influence on work performance of the first conductive pattern and work performance of the second conductive pattern.

### Embodiment VII

The embodiment provides a display substrate, comprising: the array substrate provided by the above Embodiment VI and a substrate opposite to the array substrate, and detailed content can refer to description of the above Embodiment VI and will not be repeated herein.

In the display panel provided with the embodiment, a manufacturing method of the array substrate comprises: forming a first conductive pattern, a second conductive pattern and a metal connection line on a base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in a technological process kept to be the same, and therefore an electric potential difference between the first conductive pattern and the second conductive pattern can be balanced, an electrostatic discharge phenomenon is avoided, finally, endurance capacity of a product on the electrostatic discharge phenomenon is improved, and a product yield is increased. In addition, in the embodiment, the metal connection line is removed through an etching process to make the first conductive pattern and the second conductive pattern insulated from each other, therefore avoiding influence on work performance of the first conductive pattern and work performance of the second conductive pattern.

### Embodiment VIII

The embodiment provides a display device, comprising the display panel provided by the above Embodiment VII, and detailed content can refer to description of the above Embodiment VII and will not be repeated herein.

In the display device provided by the embodiment, a manufacturing method of an array substrate comprises: forming a first conductive pattern, a second conductive pattern and a metal connection line on a base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in a technological process kept to be the same, and therefore an electric potential difference between the first conductive pattern and the second conductive pattern can be balanced, an electrostatic discharge phenomenon is avoided, finally, endurance capacity of a product on the electrostatic discharge phenomenon is improved, and a product yield is increased. In addition, in the embodiment, the metal connection line is removed through an etching process to make the first conductive pattern and the second conductive pattern insulated from each other, therefore avoiding influence on work performance of the first conductive pattern and work performance of the second conductive pattern.

In the array substrate and the manufacturing method of thereof, the display panel and the display device provided by the embodiments of the present invention, the manufacturing method comprises: forming a first conductive pattern, a second conductive pattern and a metal connection line on a base substrate, the metal connection line being connected with the first conductive pattern and the second conductive pattern; and etching the metal connection line to make the first conductive pattern and the second conductive pattern insulated from each other. The metal connection line provided by the embodiment is connected with the first conductive pattern and the second conductive pattern to make a voltage of the first conductive pattern and a voltage of the second conductive pattern in a technological process kept to be the same, and therefore an electric potential difference between the first conductive pattern and the second conductive pattern can be balanced, an electrostatic discharge phenomenon is avoided, finally, endurance capacity of a product on the electrostatic discharge phenomenon is improved, and a product yield is increased. In addition, in the embodiment, the metal connection line is removed through an etching process to make the first conductive pattern and the second conductive pattern insulated from each other, therefore avoiding influence on work performance of the first conductive pattern and work performance of the second conductive pattern.

What can be understood is that, the foregoing embodiments merely are exemplary embodiments of the disclosure in order to illustrate the principle of the embodiment, and not intended to define the scope of the disclosure. Those skilled in the art can make various changes and improvements without departing from the spirit of the disclosure, and all such changes and improvements are within the scope of the claims of the disclosure.

The present application claims priority of Chinese Patent Application No. 201510369478.6 filed on Jun. 26, 2015, the present disclosure of which is incorporated herein by reference in its entirety as part of the present application.

1. A manufacturing method of an array substrate, comprising:
forming a first conductive pattern, a second conductive pattern and a metal connection line on a base substrate, the metal connection line being connected with the first conductive pattern and the second conductive pattern; and
etching the metal connection line to make the first conductive pattern and the second conductive pattern insulated from each other.

2. The manufacturing method of the array substrate according to claim 1, wherein, the first conductive pattern includes a first gate electrode metal pattern, the second conductive pattern includes a second gate electrode metal pattern, and the gate electrode metal pattern includes a gate electrode and a gate line.

3. The manufacturing method of the array substrate according to claim 2, wherein, the first conductive pattern is a first gate electrode metal pattern, the second conductive pattern is a second gate electrode metal patter, and the gate electrode metal pattern includes a gate electrode and a gate line.

4. The manufacturing method of the array substrate according to claim 3, wherein, forming the first conductive pattern, the second conductive pattern and the metal connection line on the base substrate includes:
forming the first gate electrode metal pattern, the second gate electrode metal pattern and the metal connection line on the base substrate, the metal connection line being connected with the first gate electrode metal pattern and the second gate electrode metal pattern,
after forming the first gate electrode metal pattern, the second gate electrode metal pattern and the metal connection line on the base substrate and before etching the metal connection line to make the first conductive pattern and the second conductive pattern insulated from each other, the method includes:
forming a gate insulating layer and an active layer on the first gate electrode metal pattern, the second gate electrode metal pattern and the metal connection line, and forming a first via hole corresponding to the meal connection line in the gate insulating layer and the active layer,
etching the metal connection line to make the first conductive pattern and the second conductive pattern insulated from each other includes:
forming a transparent electrode thin film above the active layer;
etching the transparent electrode thin film and the metal connection line to form a first transparent electrode.

5. The manufacturing method of the array substrate according to claim 3, wherein, forming the first conductive pattern, the second conductive pattern and the metal connection line on the base substrate includes:
forming the first gate electrode metal pattern, the second gate electrode metal pattern and the metal connection line on the base substrate, the metal connection line being connected with the first gate electrode metal pattern and the second gate electrode metal pattern,
after forming the first gate electrode metal pattern, the second gate electrode metal pattern and the metal connection line on the base substrate and before etching the metal connection line to make the first conductive pattern and the second conductive pattern insulated from each other, the method includes:
forming a passivation layer above the first gate electrode metal pattern, the second gate electrode metal pattern and the metal connection line, and forming a first via hole corresponding to the meal connection line in the passivation layer,
etching the metal connection line to make the first conductive pattern and the second conductive pattern insulated from each other includes:
forming a transparent electrode thin film above the passivation layer;
etching the transparent electrode thin film and the metal connection line to form a second transparent electrode.

6. The manufacturing method of the array substrate according to claim 5, wherein, before forming the passivation layer above the first gate electrode metal pattern, the second gate electrode metal pattern and the metal connection line and after forming the first conductive pattern, the second conductive pattern and the metal connection line on the base substrate, the method further includes:
forming a gate insulating layer and an active layer above the first gate electrode metal pattern, the second gate electrode metal pattern and the metal connection line;
forming a first transparent electrode, a source electrode metal pattern and a drain electrode metal pattern above the gate insulating layer and the active layer.

7. The manufacturing method of the array substrate according to claim 6, wherein, forming the passivation layer above the first gate electrode metal pattern, the second gate electrode metal pattern and the metal connection line includes:
forming the passivation layer on the base substrate where the first transparent electrode, the source electrode metal pattern and the drain electrode metal pattern are formed.

8. The manufacturing method of the array substrate according to claim 6, comprising: forming a via hole corresponding to the metal connection line and the first via hole in layers where the gate insulating layer and the active layer are located simultaneously with forming the first via hole corresponding to the metal connection line in the passivation layer.

9. The manufacturing method of the array substrate according to claim 1, wherein, the first conductive pattern includes a source electrode metal pattern, the second conductive pattern includes a drain electrode metal pattern, the source electrode metal pattern includes a source electrode and a data line, and the drain electrode metal pattern includes a drain electrode.

10. The manufacturing method of the array substrate according to claim 9, wherein, forming the first conductive pattern, the second conductive pattern and the metal connection line on the base substrate includes:
forming the source electrode metal pattern, the drain electrode metal pattern and the metal connection line on the base substrate, the metal connection line being connected with the source electrode metal pattern and the drain electrode metal pattern;
after forming the source electrode metal pattern, the drain electrode metal pattern and the metal connection line on the base substrate and before etching the metal connection line to make the first conductive pattern and the second conductive pattern insulated from each other, the method includes:
forming a passivation layer above the source electrode metal pattern, the drain electrode metal pattern and the metal connection line, and forming a first via hole corresponding to the metal connection line in the passivation layer;
etching the metal connection line to make the first conductive pattern and the second conductive pattern insulated from each other includes:
forming a transparent electrode thin film above the passivation layer;
etching the transparent electrode thin film and the metal connection line to form a second transparent electrode.

11. The manufacturing method of the array substrate according to claim 1, wherein, the metal connection line includes a first sub-connection line and a second sub-connection line which are connected with each other, the first sub-connection line is connected with the first conductive pattern, and the second sub-connection line is connected with the second conductive pattern.

12. The manufacturing method of the array substrate according to claim 11, wherein, the first conductive pattern includes a gate electrode metal pattern, the second conductive pattern includes a source electrode metal pattern or a drain electrode metal pattern, the gate electrode metal pattern includes a gate electrode and a gate line, the source electrode metal pattern includes a source electrode and a data line, and the drain electrode metal pattern includes a drain electrode.

13. The manufacturing method of the array substrate according to claim 12, wherein, forming the first conductive pattern, the second conductive pattern and the metal connection line on the base substrate includes:
forming the gate electrode metal pattern and the first sub-connection line on the base substrate, the first sub-connection line being connected with the gate electrode metal pattern;
forming a gate insulating layer and an active layer above the gate electrode metal pattern and the first sub-connection line, and forming a second via hole corresponding to the first sub-connection line in the gate insulating layer and the active layer;
forming the source electrode metal pattern, the drain electrode metal pattern and the second sub-connection line above the gate insulating layer and the active layer, the second sub-connection line being connected with the source electrode metal pattern, and the second sub-connection line being connected with the first sub-connection line through the second via hole;
before etching the metal connection line to make the first conductive pattern and the second conductive pattern insulated from each other and after forming the first conductive pattern, the second conductive pattern and the metal connection line on the base substrate, the method includes:
forming a passivation layer above the source electrode metal pattern, the drain electrode metal pattern and the second sub-connection line, and forming a first via hole corresponding to the first sub-connection line or the second sub-connection line in the passivation layer;
etching the metal connection line to make the first conductive pattern and the second conductive pattern insulated from each other includes:
forming a transparent electrode thin film above the passivation layer;
etching the transparent electrode thin film and the first sub-connection line or the second sub-connection line through the first via hole to form a second transparent electrode.

14. The manufacturing method of the array substrate according to claim 12, wherein, forming the first conductive pattern, the second conductive pattern and the metal connection line on the base substrate includes:
forming the gate electrode metal pattern and the first sub-connection line on the base substrate, the first sub-connection line being connected with the gate electrode metal pattern;
forming a gate insulating layer and an active layer above the gate electrode metal pattern and the first sub-connection line, and forming a second via hole corresponding to the first sub-connection line in the gate insulating layer and the active layer;
forming the source electrode metal pattern, the drain electrode metal pattern and the second sub-connection line above the gate insulating layer and the active layer, the second sub-connection line being connected with the drain electrode metal pattern, and the second sub-connection line being connected with the first sub-connection line through the second via hole;
before etching the metal connection line to make the first conductive pattern and the second conductive pattern insulated from each other and after forming the first conductive pattern, the second conductive pattern and the metal connection line on the base substrate, the method includes:
forming a passivation layer above the source electrode metal pattern, the drain electrode metal pattern and the second sub-connection line, and forming a first via hole corresponding to the first sub-connection line or the second sub-connection line in the passivation layer;
etching the metal connection line to make the first conductive pattern and the second conductive pattern insulated from each other includes:
forming a transparent electrode thin film above the passivation layer;
etching the transparent electrode thin film and the first sub-connection line or the second sub-connection line through the first via hole to form a second transparent electrode.

15. The manufacturing method of the array substrate according to claim 1, wherein the etching includes wet etching.

16. An array substrate, manufactured by using the manufacturing method of the array substrate according to claim 1.

17. A display panel, comprising:
the array substrate according to claim 16; and
an opposed substrate, arranged opposite to the array substrate.

18. A display device, comprising the display panel according to claim 17.

19. The manufacturing method of the array substrate according to claim 2, wherein the etching includes wet etching.

20. The manufacturing method of the array substrate according to claim 3, wherein the etching includes wet etching.
